(19) United States
(12) Patent Application Publication
(10) Pub. No.: US 2026/0361169 A1
(43) Pub. Date: Nov. 12, 2026

(54) COIL SUBSTRATE, MOTOR COIL SUBSTRATE, AND MOTOR

(71) Applicant: IBIDEN CO., LTD., Gifu (JP)

(72) Inventors: Takahisa HIRASAWA, Gifu (JP); Takayuki FURUNO, Gifu (JP)

(73) Assignee: IBIDEN CO., LTD., Gifu (JP)

(21) Appl. No.: 19/393,764

(22) Filed: Nov. 19, 2025

Related U.S. Application Data
(63) Continuation of application No. PCT/JP2024/019599, filed on May 28, 2024.

(30) Foreign Application Priority Data
Jun. 1, 2023 (JP) 2023-090594

(51) Int. Cl. H02K 3/26; H02K 15/0407

(52) U.S. Cl. CPC H02K 3/26; H02K 15/0407

(57) ABSTRACT

A coil substrate includes a resin substrate having a first surface and a second surface on the opposite side with respect to the first surface, and coil wirings formed on the first surface and the second surface of the resin substrate and including a first conductor layer and an additional plating layer. The coil wirings are formed such that the first conductor layer has a trapezoidal cross-sectional shape with a lower base facing the resin substrate and an upper base on the opposite side with respect to the lower base and that the additional plating layer is covering upper and side surfaces of the first conductor layer.

### CROSS-REFERENCE TO RELATED APPLICATIONS

The present application is a continuation of and claims the benefit of priority to International Application No. PCT/JP2024/019599, filed May 28, 2024, which is based upon and claims the benefit of priority to Japanese Application No. 2023-090594, filed Jun. 1, 2023. The entire contents of these applications are incorporated herein by reference.

### BACKGROUND OF THE INVENTION

### Field of the Invention

The present invention relates to a coil substrate, a motor coil substrate, and a motor.

### Description of Background Art

Japanese Patent Application Laid-Open Publication No. 2020-181853 describes a method for manufacturing a coil substrate. The entire contents of this publication are incorporated herein by reference.

### SUMMARY OF THE INVENTION

According to one aspect of the present invention, a coil substrate includes a resin substrate having a first surface and a second surface on the opposite side with respect to the first surface, and coil wirings formed on the first surface and the second surface of the resin substrate and including a first conductor layer and an additional plating layer. The coil wirings are formed such that the first conductor layer has a trapezoidal cross-sectional shape with a lower base facing the resin substrate and an upper base on the opposite side with respect to the lower base and that the additional plating layer is covering upper and side surfaces of the first conductor layer.

According to another aspect of the present invention, a method for manufacturing a coil substrate includes preparing a resin substrate having a first metal foil layer formed on a first surface and a second metal layer formed on a second surface of the resin substrate, forming a through hole in the resin substrate such that the through hole penetrates through the resin substrate and the first and second metal foil layers, forming a chemical plating layer on surfaces of the first and second metal foil layers on the resin substrate and in the through hole formed through the resin substrate, forming an electrolytic plating layer on a surface of the chemical plating layer formed on the surfaces of the first and second metal foil layers on the resin substrate and in the through hole formed through the resin substrate, forming a plating resist pattern on the electrolytic plating layer formed on the surface of the chemical plating layer on the surfaces of the first and second metal foil layers on the resin substrate, etching exposed portions of the electrolytic plating layer, chemical plating layer, and first and second metal foil layers exposed from the plating resist pattern such that the exposed portions of the electrolytic plating layer, chemical plating layer, and first and second metal foil layers are removed, peeling off the plating resist pattern from the electrolytic plating layer formed on the surface of the chemical plating layer such that wiring patterns forming a first conductor layer is formed on the first and second surfaces of the resin substrate, and electrolytic plating on entire exposed surfaces of the wiring patterns such that a second conductor layer is formed on the entire exposed surfaces of the wiring patterns and that coil wirings including the first conductor layer and the second conductor layer are formed on the first surface and the second surface of the resin substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view illustrating a coil substrate according to an embodiment of the present invention;

FIG. 2 is a cross-sectional view between II-II of FIG. 1;

FIG. 3 is a perspective view schematically illustrating a motor coil substrate formed using a coil substrate according to an embodiment of the present invention;

FIG. 4 is a cross-sectional view schematically illustrating positions of terminals when the motor coil substrate is viewed along an axial direction;

FIG. 5 is an enlarged view of a portion (VIII) in FIG. 4;

FIG. 6 is a cross-sectional view schematically illustrating a conductor layer that forms coil wirings of a coil substrate according to an embodiment of the present invention;

FIG. 7A is a cross-sectional view schematically illustrating a method for manufacturing a coil substrate according to an embodiment of the present invention;

FIG. 7B is a cross-sectional view schematically illustrating a method for manufacturing a coil substrate according to an embodiment of the present invention;

FIG. 7C is a cross-sectional view schematically illustrating a method for manufacturing a coil substrate according to an embodiment of the present invention;

FIG. 7D is a cross-sectional view schematically illustrating a method for manufacturing a coil substrate according to an embodiment of the present invention;

FIG. 7E is a cross-sectional view schematically illustrating a method for manufacturing a coil substrate according to an embodiment of the present invention;

FIG. 7F is a cross-sectional view schematically illustrating a method for manufacturing a coil substrate according to an embodiment of the present invention;

FIG. 7G is a cross-sectional view schematically illustrating a method for manufacturing a coil substrate according to an embodiment of the present invention; and

FIG. 8 is a cross-sectional view schematically illustrating a motor formed using a motor coil substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

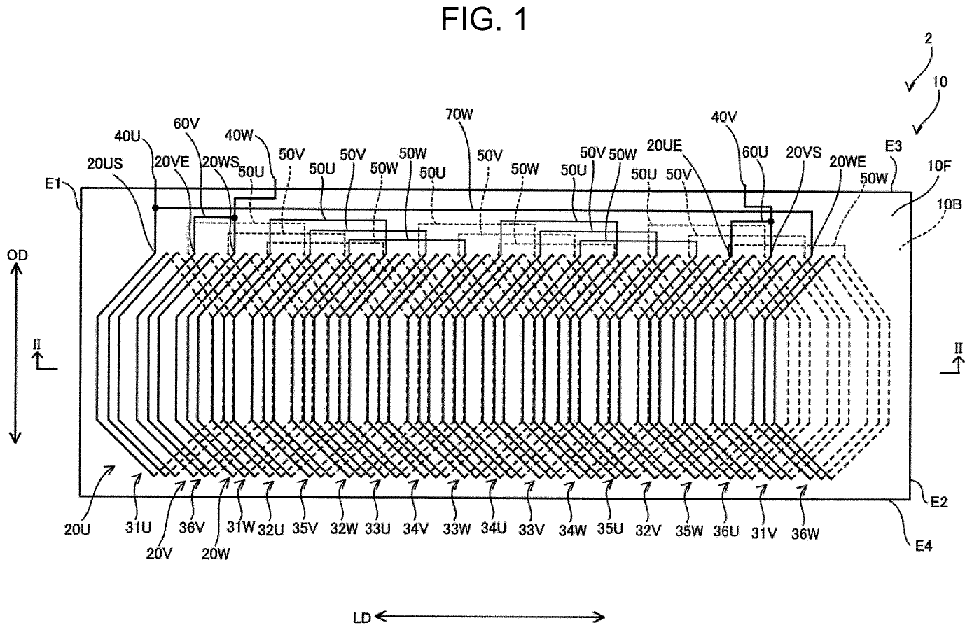

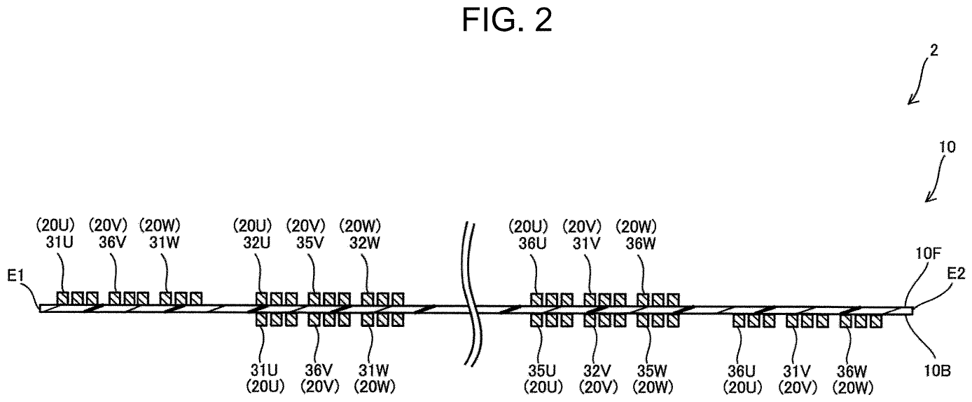

FIG. 1 is a plan view illustrating a coil substrate 2 according to an embodiment of the present invention. FIG. 2 is a cross-sectional view between II-II of FIG. 1.

As illustrated in FIG. 1, the coil substrate 2 has a flexible substrate 10, a U-phase coil (20U), a V-phase coil (20V), a W-phase coil (20W), a U-phase terminal (40U), a V-phase terminal (40V), a W-phase terminal (40W), multiple inter-coil connection wirings (50U, 50V, 50W), multiple interphase connection wirings (60U, 60V), and a return wiring (70W).

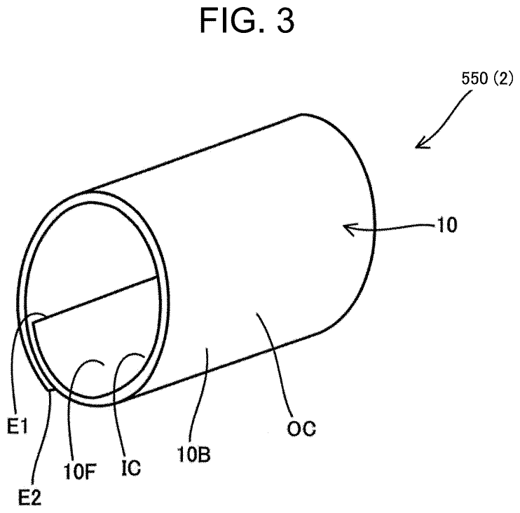

The flexible substrate 10 is a resin substrate having a first surface (10F) and a second surface (10B) on an opposite side with respect to the first surface (10F). The flexible substrate 10 is formed using an insulating resin such as polyimide or polyamide. The flexible substrate 10 is flexible. The flexible substrate 10 is formed in a rectangular shape having four sides, first side (E1)-fourth side (E4). The first side (E1) is a short side on one end side of the flexible substrate 10 in a longitudinal direction (arrow (LD) direction in FIG. 1). The second side (E2) is a short side on the other end side in the longitudinal direction. The first side (E1) and the second side (E2) are short sides extending along an orthogonal direction (arrow (OD) direction in FIG. 1) that is orthogonal to the longitudinal direction. The third side (E3) and the fourth side (E4) are long sides extending in the longitudinal direction. As will be described in detail later, when the coil substrate 2 is wound into a cylindrical shape to form a motor coil substrate 550 (see FIG. 3 described below), the first surface (10F) is positioned on an inner circumferential side and the second surface (10B) is positioned on an outer circumferential side. It is also possible that the first surface (10F) is positioned on the outer circumferential side and the second surface (10B) is positioned on the inner circumferential side.

The U-phase terminal (40U), the V-phase terminal (40V), and the W-phase terminal (40W) are all formed on the third side (E3) of the flexible substrate 10. As illustrated in FIG. 1, the U-phase terminal (40U) is connected to a starting end (20US) of the U-phase coil (20U). At the same time, the U-phase terminal (40U) is connected to a terminating end (20WE) of the W-phase coil (20W) via the return wiring (70W). The V-phase terminal (40V) is connected to a starting end (20VS) of the V-phase coil (20V). At the same time, the V-phase terminal (40V) is connected to a terminating end (20UE) of the U-phase coil (20U) via the inter-phase connection wiring (60U). The W-phase terminal (40W) is connected to a starting end (20WS) of the W-phase coil (20W). At the same time, the W-phase terminal (40W) is connected to a terminating end (20VE) of the V-phase coil (20V) via the inter-phase connection wiring (60V).

The U-phase coil (20U), the V-phase coil (20V), and the W-phase coil (20W) respectively constitute the U phase, the V phase, and the W phase of a three-phase motor.

### U-Phase Coil

As illustrated in FIG. 1, the U-phase coil (20U) includes six coils (31U, 32U, 33U, 34U, 35U, 36U). The six coils (31U-36U) are formed in this order from the starting end (20US) to the terminating end (20UE) of the U-phase coil (20U).

The six coils (31U-36U) are each formed by forming a first wiring, which forms a half turn of one turn, on the first surface (10F) side, forming a second wiring, which forms the remaining half turn of the one turn, on the second surface (10B) side, and forming adjacent turns in a staggered manner. The first wiring and the second wiring are electrically connected via a via conductor that penetrates the flexible substrate 10. The coil wiring of the U-phase is formed by these first and second wirings.

### V-Phase Coil

As illustrated in FIG. 1, the V-phase coil (20V) includes six coils (31V, 32V, 33V, 34V, 35V, 36V). The six coils (31V-36V) are formed in this order from the starting end (20VS) to the terminating end (20VE) of the V-phase coil (20V).

The six coils (31V-36V) are each formed by forming a first wiring, which forms a half turn of one turn, on the first surface (10F) side, forming a second wiring, which forms the remaining half turn of the one turn, on the second surface (10B) side, and forming adjacent turns in a staggered manner. The first wiring and the second wiring are electrically connected via a via conductor that penetrates the flexible substrate 10. The coil wiring of the V-phase is formed by these first and second wirings.

### W-Phase Coil

As illustrated in FIG. 1, the W-phase coil (20W) includes six coils (31W, 32W, 33W, 34W, 35W, 36W). The six coils (31W-36W) are formed in this order from the starting end (20WS) to the terminating end (20WE) of the W-phase coil (20W).

The six coils (31W-36W) are each formed by forming a first wiring, which forms a half turn of one turn, on the first surface (10F) side, forming a second wiring, which forms the remaining half turn of the one turn, on the second surface (10B) side, and forming adjacent turns in a staggered manner. The first wiring and the second wiring are electrically connected via a via conductor that penetrates the flexible substrate 10. The coil wiring of the W-phase is formed by these first and second wirings.

As illustrated in FIG. 1, in the embodiment, the wirings of the coils (20U, 20V, 20W) are each formed in a hexagonal shape. In other examples, the wirings of the coils (20U, 20V, 20W) may be formed in any shape, such as a circle (perfect circle, ellipse), a triangle, a quadrangle (square, rectangle, rhombus), a pentagon, or a polygon with seven or more sides. Further, it is not limited to having identical wiring formation shapes for all the coils; the wiring formation shapes may differ between the coils. The number of turns of one coil winding is not particularly limited, but may be one or more, and is preferably 3 to 7. A coil wiring is formed by forming a half turn on the first surface, forming a half turn on the second surface, and connecting them via a through hole. Further, it is also possible to form a half turn on the second surface and form a half turn on the first surface. In this case, a half turn refers to half of a coil wiring. Further, it is possible to form a ¼ turn on the first surface and a ¼ turn on the second surface, connect them via a through hole, and form a total of a half turn on either the first surface or the second surface.

Further, a coil wiring may be formed on either the first surface or the second surface. In this case, it is possible that a coil wiring on the first surface and a coil wiring on the second surface fully or partially overlap, or do not overlap.

### Motor Coil Substrate

FIG. 3 is a perspective view schematically illustrating a motor coil substrate 550 formed using the coil substrate 2 of the embodiment. As illustrated in FIG. 3, the motor coil substrate 550 for a motor is formed by winding the coil substrate 2 of the embodiment (FIGS. 1 and 2) into a substantially cylindrical shape. When the coil substrate 2 is wound into a cylindrical shape, the coil substrate 2 is wound multiple turns around an axis extending in the orthogonal direction (an axis extending parallel to the first side (E1)) with the first side (E1) (FIG. 1) as a starting point. Further, the number of turns the coil substrate is wound is not particularly limited. When the coil substrate 2 is wound into a cylindrical shape, the first surface (10F) of the flexible substrate 10 is positioned on the inner circumferential side, and the second surface (10B) is positioned on the outer circumferential side. When the coil substrate 2 is wound into a cylindrical shape, it is also possible that the first surface (10F) of the flexible substrate 10 is positioned on the outer circumferential side, and the second surface (10B) is positioned on the inner circumferential side.

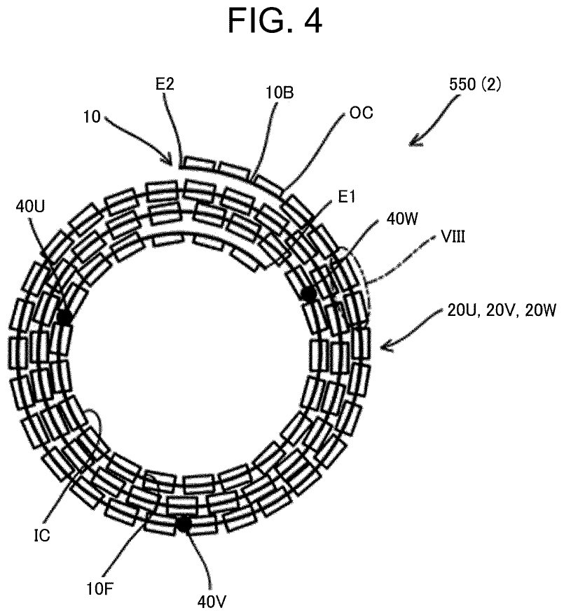

FIG. 4 schematically illustrates positions of the terminals when the motor coil substrate 550 is viewed along an axial direction. As illustrated in FIG. 4, the U-phase terminal (40U), the V-phase terminal (40V), and the W-phase terminal (40W) are formed at substantially 120-degree intervals in a circumferential direction. The U-phase terminal (40U) and the W-phase terminal (40W) are formed on an inner circumferential surface.

The V-phase terminal (40V) is formed on an outer circumferential surface. The U-phase terminal (40U), the W-phase terminal (40W), and the V-phase terminal (40V) may be formed arbitrarily.

As illustrated in FIG. 4, the motor coil substrate 550 has an inner circumferential surface (IC) and an outer circumferential surface (OC). Cylindricity of the outer circumferential surface (OC) is greater than 0.0 mm and equal to or less than 0.3 mm.

When the cylindricity of the outer circumferential surface (OC) is greater than 0.0 mm and equal to or less than 0.3 mm, the motor coil substrate 550 does not roll evenly on a flat surface. When the cylindricity of the outer circumferential surface (OC) is greater than 0.0 mm and equal to or less than 0.3 mm, bonding strength with the yoke during motor formation is increased. A motor with stable performance can be obtained. Further, the cylindricity of the outer circumferential surface (OC) of the motor coil substrate 550 is preferably greater than 0.0 mm and equal to or less than 0.2 mm. When the cylindricity of the outer circumferential surface (OC) is greater than 0.0 mm and equal to or less than 0.2 mm, the bonding strength with the yoke during motor formation can be increased and stability can be improved. Therefore, even when it is operated as a motor, the motor coil substrate 550 is not positionally displaced, and a motor with stable performance can be obtained.

The cylindricity of the outer circumferential surface (OC) is measured using a V-block measurement method. That is, the cylindricity of the outer circumferential surface (OC) is measured by placing the motor coil substrate 550 on a V-block, rotating it one turn, measuring a deviation in a direction perpendicular to the axis at three different locations, and calculating an average value thereof.

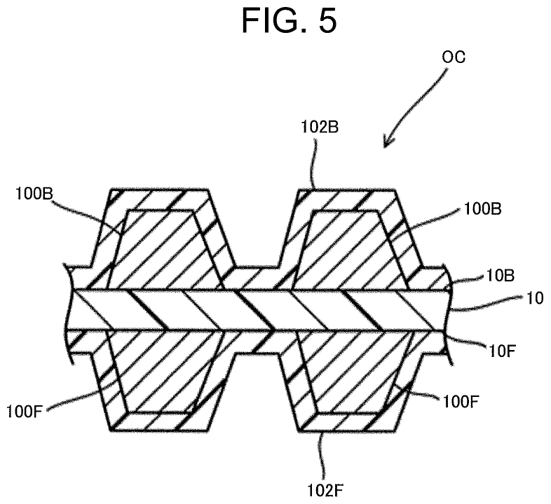

FIG. 5 is an enlarged view of a portion (VIII) in FIG. 4, illustrating an example of a structure of a terminal. As illustrated in FIG. 5, conductor layers (100F, 100B) of the coils (20U, 20V, 20W) are respectively formed on the first surface (10F) and the second surface (10B), and insulating layers (102F, 102B) are respectively formed on the conductor layers (100F, 100B) of the coils (20U, 20V, 20W). Further, the inter-coil connection wirings (50U, 50V, 50W), the inter-phase connection wirings (60U, 60V), and the return wiring (70W) are covered by the insulating layers (102F, 102B). The insulating layers may be formed so as to conform to the wirings, or may cover the circuits and also fill spaces between adjacent wirings. By forming the insulating layers (102F, 102B), the conductor layers (100F, 100B) are not exposed and there is no contact between conductor layers (100F, 100B) adjacent in the longitudinal direction of the flexible substrate 10 or between conductor layers (100F, 100B) adjacent in a radial direction in a cross-section when the coil substrate 2 is wound, and thus, insulation is maintained. A method of forming the insulating layers (102F, 102B) is not particularly limited, and they can be formed by printing a liquid resin, by electro-depositing a resin, or by applying a coverlay. Examples of the resin include insulating resins such as polyimide and epoxy resin. In FIG. 5, the insulating layers (102F, 102B) are formed so as to conform to the conductor layers (100F, 100B). However, it is also possible that the insulating layers are formed to cover upper surfaces of the conductor layers (100F, 100B) and fill spaces between the conductor layers (100F, 100B). The insulating layers (102F, 102B) are not particularly limited in thickness, but are preferably formed to each have a thickness of about 1 μm or more and 30 μm or less. In FIG. 5, the conductor layers (100F, 100B) are symmetrically formed with the flexible substrate 10 sandwiched in between. However, it is also possible that the conductor layers (100F, 100B) partially overlap each other with the flexible substrate 10 sandwiched in between, or do not overlap each other with the flexible substrate 10 sandwiched in between.

In this case, a cross section of the motor coil substrate 550 is composed of the flexible substrate 10, the conductor layers, which are the wirings of the phases, and the insulating layers, which cover the conductor layers. In this case, a result obtained by calculating a cross-sectional area of all the conductor layers in a cross-sectional area of the motor coil substrate 550 is a space factor of the coils. In this case, the space factor of the coils in the cross section of the motor coil substrate 550 is 50% or more and 99% or less. A high space factor of the coil conductors is ensured. Therefore, when a motor is formed using the motor coil substrate 550 of the embodiment, high torque can be obtained. A high-performance motor can be obtained. In this case, a method for calculating the space factor of the coils is: Space factor=((sum of cross-sectional areas of conductor parts)/(coil cross-sectional area))×100.

The combined coil space factor of the coils (20U, 20V, 20W) in a cross section of the motor coil substrate 550 is 50% or more and 99% or less. By using a motor coil substrate 550 with a space factor of 50% or more and 99% or less, a high-torque motor can be obtained, and problems due to eddy currents or electrical resistance can also be suppressed. As a result, a high-performance motor can be obtained. Further, when the motor coil substrate 550 of the embodiment is applied to a compact motor, torque can be increased, and a high-performance motor can be obtained. In the present specification, a compact motor refers to a motor with an outer diameter of 50 mm or less.

Further, the space factor of the coils in a cross section of the motor coil substrate 550 is preferably 55% or more and 90% or less. By using a motor coil substrate 550 with a coil space factor of 55% or more and 90% or less, a high-torque motor can be obtained. Further, when the motor coil substrate 550 of the embodiment is applied to a compact motor, torque can be increased, and problems due to eddy currents or electrical resistance can also be suppressed. As a result, a high-performance motor can be obtained.

Further, the space factor of the coils in a cross section of the motor coil substrate 550 is more preferably 60% or more and 80% or less. A high space factor of the coil conductors can be ensured, and when it is wound into a cylindrical shape, a predetermined cylindrical shape can be achieved. Further, even in a compact motor, a high space factor of the coil conductors can be ensured, and when it is wound into a cylindrical shape, a predetermined cylindrical shape can be obtained, and torque can be increased, and problems due to eddy currents or electrical resistance can also be suppressed. As a result, a high-performance motor can be obtained.

When the motor coil substrate 550 is formed, the number of turns of the coil substrate 2 is arbitrary. The number of turns of the coil substrate 2 is preferably 2 or more and 10 or less. By setting the number of turns to 2 or more and 10 or less, the cylindricity of the outer circumferential surface (OC) of the formed motor coil substrate 550 is greater than 0.0 mm and equal to or less than 0.3 mm, as described above. As a result, degradation in motor performance can be suppressed.

The space factor of the coils in a cross section of the motor coil substrate 550 is 50% or more and 99% or less, and the cylindricity of the outer circumferential surface (OC) of the motor coil substrate 550 is greater than 0.0 mm and equal to or less than 0.3 mm. In the motor coil substrate 550, the space factor of the coils is 50% or more and 99% or less and the cylindricity of the outer circumferential surface (OC) is greater than 0.0 mm and equal to or less than 0.3 mm. When a motor is formed using the motor coil substrate 550, the bonding strength with the yoke during motor formation is increased, high torque is obtained, and problems due to eddy currents or electrical resistance are also suppressed. As a result, a high-performance motor can be obtained.

Further, the space factor of the coils in a cross section of the motor coil substrate 550 is 55% or more and 90% or less, and the cylindricity of the outer circumferential surface (OC) of the motor coil substrate 550 is greater than 0.0 mm and equal to or less than 0.3 mm. In the motor coil substrate 550, the space factor of the coils is 55% or more and 90% or less and the cylindricity of the outer circumferential surface (OC) of the motor coil substrate 550 is greater than 0.0 mm and equal to or less than 0.3 mm. When a motor is formed using the motor coil substrate 550, the bonding strength with the yoke during motor formation is increased, high torque is obtained, and problems due to eddy currents or electrical resistance are also suppressed. As a result, a high-performance motor can be obtained.

Further, the space factor of the coils in a cross section of the motor coil substrate 550 is 60% or more and 80% or less, and the cylindricity of the outer circumferential surface (OC) of the motor coil substrate 550 is greater than 0.0 mm and equal to or less than 0.3 mm. In the motor coil substrate 550, the space factor of the coils is 60% or more and 80% or less and the cylindricity of the outer circumferential surface (OC) of the motor coil substrate 550 is greater than 0.0 mm and equal to or less than 0.3 mm. When a motor is formed using the motor coil substrate 550, the bonding strength with the yoke during motor formation is increased, high torque is obtained, and problems due to eddy currents or electrical resistance are also suppressed. As a result, a high-performance motor can be obtained.

The space factor of the coils in a cross section of the motor coil substrate 550 is 50% or more and 99% or less, and the cylindricity of the outer circumferential surface (OC) of the motor coil substrate 550 is greater than 0.0 mm and equal to or less than 0.2 mm. In the motor coil substrate 550, the space factor of the coils is 50% or more and 99% or less and the cylindricity of the outer circumferential surface (OC) is greater than 0.0 mm and equal to or less than 0.2 mm. When a motor is formed using the motor coil substrate 550, the bonding strength with the yoke during motor formation is increased, high torque is obtained, and problems due to eddy currents or electrical resistance are also suppressed. As a result, a high-performance motor can be obtained.

Further, the space factor of the coils in a cross section of the motor coil substrate 550 is 55% or more and 90% or less, and the cylindricity of the outer circumferential surface (OC) of the motor coil substrate 550 is greater than 0.0 mm and equal to or less than 0.2 mm. In the motor coil substrate 550, the space factor of the coils is 55% or more and 90% or less and the cylindricity of the outer circumferential surface (OC) of the motor coil substrate 550 is greater than 0.0 mm and equal to or less than 0.2 mm. When a motor is formed using the motor coil substrate 550, the bonding strength with the yoke during motor formation is increased, high torque is obtained, and problems due to eddy currents or electrical resistance are also suppressed. As a result, a high-performance motor can be obtained.

Further, the space factor of the coils in a cross section of the motor coil substrate 550 is 60% or more and 80% or less, and the cylindricity of the outer circumferential surface (OC) of the motor coil substrate 550 is greater than 0.0 mm and equal to or less than 0.2 mm. In the motor coil substrate 550, the space factor of the coils is 60% or more and 80% or less and the cylindricity of the outer circumferential surface (OC) of the motor coil substrate 550 is greater than 0.0 mm and equal to or less than 0.2 mm. When a motor is formed using the motor coil substrate 550, the bonding strength with the yoke during motor formation is increased, high torque is obtained, and problems due to eddy currents or electrical resistance are also suppressed. As a result, a high-performance motor can be obtained.

When the motor coil substrate 550 of the embodiment is applied to a compact motor, torque can be increased, and a high-performance motor can be obtained.

The motor coil substrate 550 of the embodiment is used in a slotless motor. In another example, the motor coil substrate 550 may be used in a motor other than a slotless motor.

A diameter of the outer circumferential surface (OC) (outer diameter of a cross section) of the motor coil substrate 550 is 50 mm or less. The diameter of the outer circumferential surface (OC) (outer diameter of a cross section) of the motor coil substrate 550 is preferably 30 mm or less. By forming a compact motor using a motor coil substrate 550 with a diameter of 50 mm or less, degradation in motor performance can be effectively suppressed. The diameter of the outer circumferential surface (OC) of the motor coil substrate 550 is measured using a caliper. In the embodiment illustrated in FIG. 1, the space factor of the coils in a cross-sectional area of the motor coil substrate 550 is 70%. The ratio of the wirings in the total weight of the motor coil substrate 550 is 93%.

The cylindricity of the outer circumferential surface (OC) is 0.1 mm. The diameter of the outer circumferential surface (OC) (outer diameter of a cross section) of the motor coil substrate 550 is 16 mm.

### Coil Wirings

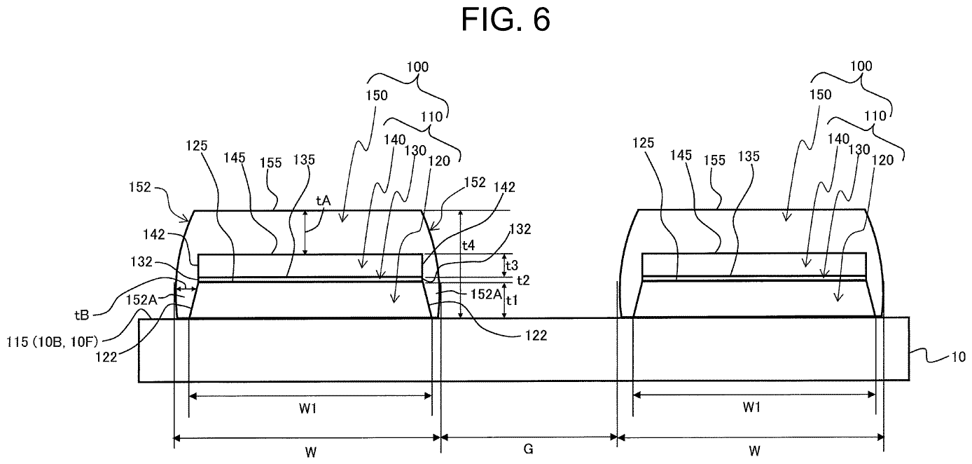

Next, a structure of the conductor layers (100F, 100B) that form the coil wirings is described. FIG. 6 is a schematic cross-sectional view illustrating an example of a cross-sectional structure of the conductor layer (100F) or (100B) (hereinafter, when no distinction between them is necessary, both are simply referred to as “conductor layer 100”). As illustrated in FIG. 6, the conductor layer 100 includes a first conductor layer 110 formed on the first surface (10F) or the second surface (10B) of the flexible substrate 10, and a second conductor layer 150 (additional plating layer).

The first conductor layer 110 includes a metal foil layer 120, a chemical plating layer 130 formed on the metal foil layer 120, and an electrolytic plating layer 140 formed on the chemical plating layer 130.

The metal foil layer 120 contains Cu, Ni, Al, or the like, and is formed by being attached to the flexible substrate 10. The metal foil layer 120 preferably contains Cu as a main component, as it facilitates wiring formation and has excellent electrical properties. A second boundary surface 125 is formed at a boundary between the metal foil layer 120 and the chemical plating layer 130. The second boundary surface 125 is located on an upper surface of the metal foil layer 120. A first boundary surface 115, which is a boundary between the metal foil layer 120 and the flexible substrate 10, is located on a lower surface of the metal foil layer 120. The first boundary surface 115 is the same as the first surface (10F) or the second surface (10B). The first boundary surface 115 is a surface facing the flexible substrate 10. The metal foil layer 120 has a substantially trapezoidal cross-sectional shape, with the first boundary surface 115 as a lower base and the second boundary surface 125 as an upper base. The lower base of the metal foil layer 120 has a width (W1). Side surfaces (122, 122) of the metal foil layer 120 are inclined with respect to an up-down direction in the drawing, which is orthogonal to the first surface (10F) or the second surface (10B) of the flexible substrate 10. The metal foil layer 120 has a thickness (t1). t1=10 to 50 μm.

The chemical plating layer 130 is formed by chemical plating containing Cu, Ni, or the like. The chemical plating layer 130 preferably contains Cu as a main component, as it facilitates wiring formation. A third boundary surface 135 is formed at a boundary between the chemical plating layer 130 and the electrolytic plating layer 140. The third boundary surface 135 is located on an upper surface of the chemical plating layer 130.

The second boundary surface 125 is located on a lower surface of the chemical plating layer 130. The chemical plating layer 130 has side surfaces (132, 132). The chemical plating layer 130 has a thickness (t2). t2=1 to 5 μm.

The electrolytic plating layer 140 is formed by electrolytic plating containing Cu or Ni. The electrolytic plating layer 140 preferably contains Cu as a main component, as it facilitates wiring formation and has excellent electrical properties. The electrolytic plating layer 140 has an upper surface 145. The third boundary surface 135 is located on a lower surface of the electrolytic plating layer 140. Although not clearly illustrated, the electrolytic plating layer 140 has a substantially trapezoidal cross-sectional shape, with the third boundary surface 135 as a lower base and the upper surface 145 as an upper base. Side surfaces (142, 142) of the electrolytic plating layer 140 are inclined with respect to the up-down direction in the drawing, which is orthogonal to the first surface (10F) or the second surface (10B) of the flexible substrate 10. The electrolytic plating layer 140 has a thickness (t3). t3=10 to 50 μm. The inclination of the side surfaces 142 of the electrolytic plating layer 140 is steeper than the inclination of the side surfaces 122 of the metal foil layer 120.

With the shapes of the metal foil layer 120, the chemical plating layer 130, and the electrolytic plating layer 140 as described above, the first conductor layer 110 has a substantially trapezoidal cross-sectional shape, with a lower base (the first boundary surface 115) facing the flexible substrate 10 and an upper base (the upper surface 145) on an opposite side with respect to the lower base. The first conductor layer 110 has an overall thickness (t1+t2+t3). t1+t2+t3≥15 μm. The first conductor layer 110 has a width (W1) (the width of the lower base of the metal foil layer 120). W1≥55 μm. The inclination of the side surfaces 122 of the metal foil layer 120 in the first conductor layer 110 is gentler than the inclination of the side surfaces 142 of the electrolytic plating layer 140. Further, an inner angle of the side surfaces 122 of the metal foil layer 120 is smaller than an inner angle of the electrolytic plating layer 140. Since the side surfaces of the first conductor layer 110 have different inclination angles, contact between adjacent conductor layers 100 is suppressed when the coil substrate 2 is wound, and the winding of the coil substrate 2 is facilitated. As a result, a predetermined cylindrical shape is achieved, thereby suppressing rewinding. In other words, the cross-sectional shape of the first conductor layer 110 may have side surfaces with different inclinations. Further, side surfaces of the substantially trapezoidal shape may have side surfaces with different inclinations. Since the cross-sectional shape of the first conductor layer 110 of the coil wirings is a trapezoidal shape having side surfaces with different inclination angles, even when an additional plating is formed to increase a thickness in a thickness direction in order to increase the space factor of the coils, in a motor coil substrate obtained by winding the coil substrate into a substantially cylindrical shape, contact between a coil wiring and an adjacent wiring is suppressed, and a cross-sectional shape of the motor coil substrate also becomes substantially circular. A motor coil substrate obtained by winding the coil substrate into a substantially cylindrical shape (cylindrical shape) is synonymous with a motor coil substrate obtained by forming the coil substrate into a substantially cylindrical shape (cylindrical shape).

The cross-sectional shapes of the metal foil layer 120 and the electrolytic plating layer 140 are not limited to trapezoids, but may also be other quadrilateral shapes such as squares or rectangles. The cross-sectional shapes of the metal foil layer 120, the chemical plating layer 130, and the electrolytic plating layer 140 may be the same (for example, trapezoidal) or may be different from each other.

The second conductor layer 150 is formed by electrolytic plating containing Cu and Ni. The second conductor layer 150 preferably contains Cu as a main component, as it facilitates wiring formation and has excellent electrical properties. The second conductor layer 150 covers the upper and side surfaces of the first conductor layer 110. The upper surface of the first conductor layer 110 is the upper surface 145 of the electrolytic plating layer 140. The side surfaces of the first conductor layer 110 are the side surfaces (122, 132, 142) of the metal foil layer 120, the chemical plating layer 130, and the electrolytic plating layer. Recesses may be present in some of the side surfaces. The second conductor layer 150 has a thickness of 5 μm or more. A thickness (tA) of a portion of the second conductor layer 150 that covers the upper surface of the first conductor layer 110 is greater than the thickness (t1+t2+t3) of the first conductor layer 110. In other words, the thickness of the portion of the second conductor layer (additional plating layer) 150 that covers the upper surface of the first conductor layer 110 is greater than the thickness of the first conductor layer 110. The thickness (tA) is a distance from an upper surface 155 of the second conductor layer 150 to the upper surface 145 of the electrolytic plating layer 140. A side wall 152 of the second conductor layer 150 includes a reverse-taper portion (152A) that becomes thinner toward the flexible substrate 10 side. In the reverse-taper portion (152A), a distance (tB) from the first conductor layer 110 to an outer surface of the second conductor layer 150 decreases toward the flexible substrate 10.

A relationship between the thickness (tA) of the second conductor layer 150 and the distance (tB) to the outer surface of the second conductor layer 150 is: 1.0≤tA/tB≤1.4. Having 1.0=tA/tB≤1.4 in the second conductor layer 150 increases the space factor of the coils and facilitates the winding of the coil substrate 2. In other words, the space factor of the coils can be set to a predetermined ratio while keeping the cylindricity of the motor coil substrate 550 within a predetermined range. Further, the relationship between the thickness (tA) of the second conductor layer 150 and the distance (tB) to the outer surface of the second conductor layer 150 is preferably: 1.0≤tA/tB≤1.2. Having 1.0≤tA/tB≤1.2 in the second conductor layer 150 can increase the space factor of the coils, facilitate the winding of the coil substrate 2, and suppress rewinding. The second conductor layer 150 has an overall thickness (t4). The second conductor layer 150 has a width (W). When the second conductor layer 150 has the reverse-taper portion (152A), contact between adjacent conductor circuits is prevented when the coil substrate 2 is wound. Therefore, short-circuiting is suppressed.

With the shapes of the first conductor layer 110 and the second conductor layer 150 as described above, the conductor layer 100 has an overall thickness (t4) (=the thickness of the second conductor layer 150). 20 μm≤t4≤200 um. Preferably, 40 μm≤t4≤100 μm. The conductor layer 100 has an overall width (W) (=the width of the second conductor layer 150). 60 μm≤W600 μm. Preferably, 100 μm≤W=300 μm. A distance (gap) (G) is provided between adjacent conductor layers 100. 10 μm≤G≤50 μm.

Of the conductor layer 100, the overall width (W) is 60 μm≤W=600 μm, and the overall thickness (t4) is 20 μm≤t4≤200 μm. By setting the overall width (W) and the overall thickness (t4) of the conductor layer 100 within the predetermined ranges, influence of wiring resistance or eddy currents can be stably reduced. Further, an effect of increasing the space factor of the coils is also achieved.

Of the conductor layer 100, the overall width (W) is 60 μm≤W=600 μm, and the overall thickness (t4) is 40 μm≤t4=100 μm. By setting the overall width (W) and the overall thickness (t4) of the conductor layer 100 within the predetermined ranges, influence of wiring resistance or eddy currents can be stably reduced. Further, an effect of increasing the space factor of the coils is also achieved.

Of the conductor layer 100, the overall width (W) is 100 μm≤W=300 μm, and the overall thickness (t4) is 20 μm≤t≤200 μm. By setting the overall width (W) and the overall thickness (t4) of the conductor layer 100 within the predetermined ranges, influence of wiring resistance or eddy currents can be stably reduced. Further, an effect of increasing the space factor of the coils is also achieved.

Of the conductor layer 100, the overall width (W) is 100 μm≤W=300 μm, and the overall thickness (t4) is 40 μm≤t4≤100 μm. By setting the overall width (W) and the overall thickness (t4) of the conductor layer 100 within the predetermined ranges, influence of wiring resistance or eddy currents can be stably reduced. Further, an effect of increasing the space factor of the coils is also achieved.

### Method for Manufacturing Coil Substrate

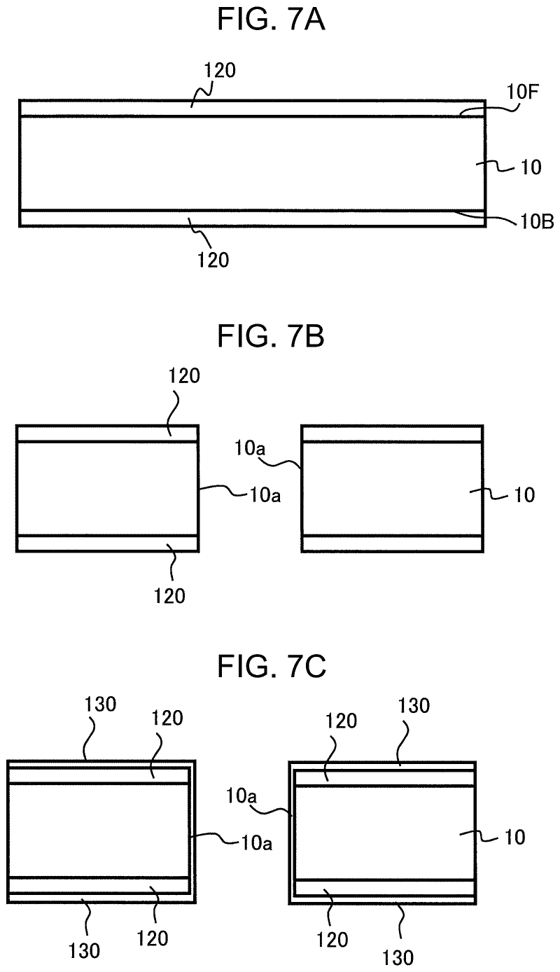

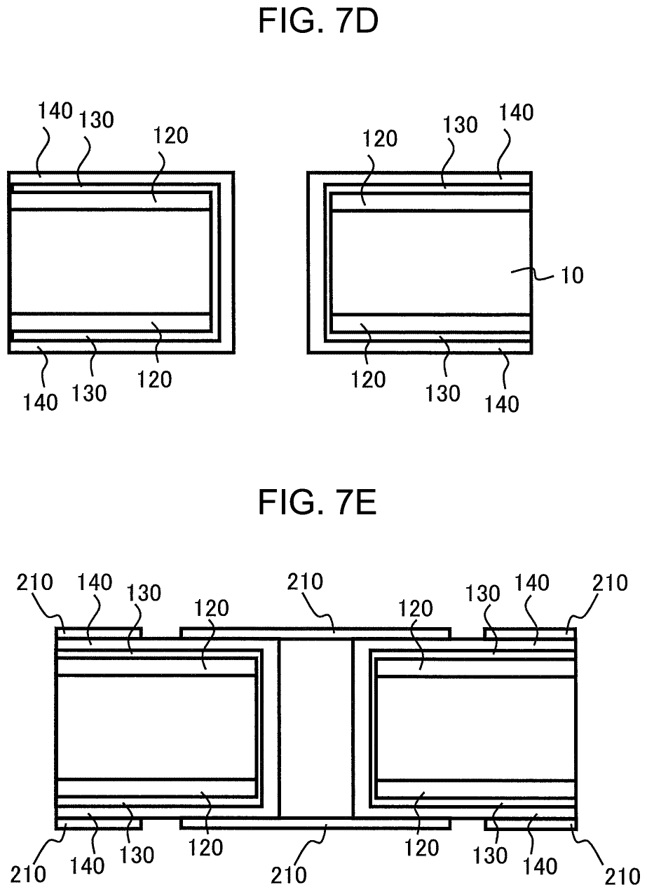

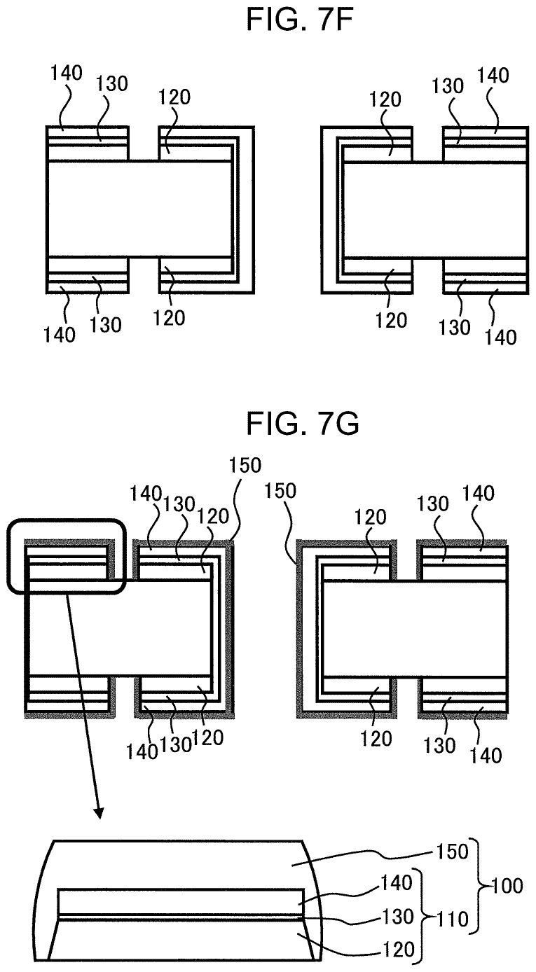

The coil substrate 2 of the embodiment can be manufactured using any method. For example, the coil substrate 2 is formed using a tenting method using as a starting material a flexible substrate 10 having a metal foil. An example of the manufacturing process is described below with reference to FIGS. 7A to 7G. FIGS. 7A to 7G are schematic cross-sectional views illustrating a method for manufacturing the coil substrate 2 of the embodiment.

As illustrated in FIG. 7A, the flexible substrate 10 having the metal foil layer 120 formed on the first surface (10F) and the second surface (10B) is prepared.

As illustrated in FIG. 7B, a through hole (10a) penetrating the flexible substrate 10 is formed by drilling or laser processing. Instead of the through hole (10a), a non-through hole may be formed with the metal foil layer 120 remaining on one side.

As illustrated in FIG. 7C, the chemical plating layer 130 is formed on the surface of the metal foil layer 120 and in the through hole (10a) of the flexible substrate 10 by chemical plating containing Cu as a main component.

As illustrated in FIG. 7D, using the chemical plating layer 130 as a seed layer, the electrolytic plating layer 140 is formed on the surface of the chemical plating layer 130 by electrolytic plating containing Cu as a main component.

As illustrated in FIG. 7E, a plating resist pattern 210 is formed on the electrolytic plating layer 140.

As illustrated in FIG. 7F, the electrolytic plating layer 140, the chemical plating layer 130, and the metal foil layer 120 exposed from the plating resist pattern 210 are removed by etching. After that, the plating resist pattern 210 is peeled off, and wiring patterns are completed.

As illustrated in FIG. 7G, the second conductor layer 150 is formed on all exposed surfaces of the wiring patterns by electrolytic plating containing Cu as a main component, and the conductor layer 100 is completed.

### Motor

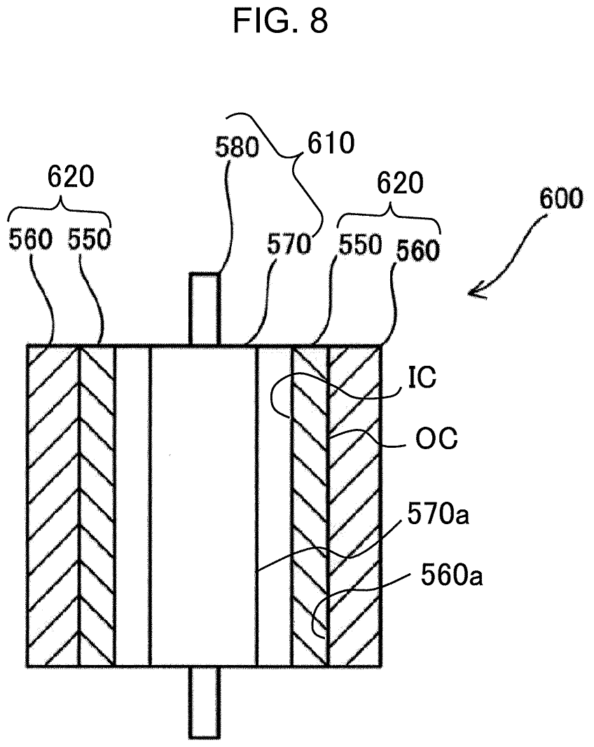

FIG. 8 is a cross-sectional view schematically illustrating a motor 600 using the motor coil substrate 550 of the embodiment (FIGS. 3 to 5). The motor 600 is formed by positioning the motor coil substrate 550 on an inner side of a yoke 560, and positioning a rotation shaft 580 and a magnet 570 fixed to the rotation shaft 580 on an inner side of the motor coil substrate 550. The motor 600 of the embodiment is a slotless motor. The magnet 570 and the rotary shaft 580 constitute a rotor 610, and the motor coil substrate 550 and the yoke 560 constitute a stator 620.

The motor coil substrate 550 is positioned on an inner side of the cylindrical yoke 560. The outer circumferential surface (OC) of the motor coil substrate 550 and an inner circumferential surface (560a) of the yoke 560 are fixed by bonding. The inner circumferential surface (IC) of the motor coil substrate 550 and an outer circumferential surface (570a) of the magnet 570 are positioned so as to face each other in a radial direction with a predetermined gap therebetween.

In the above embodiment, the magnet 570 is provided on the rotor 610 and the motor coil substrate 550 is provided on the stator 620. However, the present invention is not limited to this. A structure in which the magnet 570 is provided on the stator and the motor coil substrate 550 is provided on the rotor may also be used.

In the above, the structures of the coil substrate 2 (FIGS. 1 and 2), the motor coil substrate 550 (FIGS. 3 to 5), and the motor 600 (FIG. 8) of the embodiment have been described. As described above, in the coil substrate 2 of the embodiment, the second conductor layer 150 is further formed to cover the upper and side surfaces of the first conductor layer 110, which is composed of the metal foil layer 120, the chemical plating layer 130, and the electrolytic plating layer 140. Therefore, the width and thickness of the coil wirings primarily formed by the first conductor layer 110 can be supplemented and adjusted to predetermined values by the subsequent second conductor layer 150. In the coil substrate 2 of the embodiment, influence of wiring resistance or eddy currents can be reduced, and further, there is also an effect that the space factor of the coils can be increased.

In the coil substrate 2, when the width of the coil wirings is less than 60 μm or the thickness is less than 20 μm, the influence of wiring resistance becomes significant. In the coil substrate 2 of the embodiment, when the width (W) of the conductor layer 100 is 60 μm or more and the thickness (t4) is 20 μm or more, the influence of wiring resistance can be reliably reduced. When the width of the coil wirings exceeds 600 μm or the thickness exceeds 200 μm, the influence of eddy currents becomes significant. When the width (W) of the conductor layer 100 is 600 μm or less and the thickness (t4) is 200 μm or less, the influence of eddy currents can be reliably reduced.

In the coil substrate 2 of the embodiment, the thickness (tA) of the portion of the second conductor layer 150 that covers the upper surface of the first conductor layer 110 is greater than the thickness (t1+t2+t3) of the first conductor layer 110. By significantly supplementing the thickness of the upper portion of the first conductor layer 110 with the thickness of the second conductor layer 150, the overall thickness of the conductor layer 100 can be prevented from becoming excessively small.

In the coil substrate 2 of the embodiment, the sidewall 152 of the second conductor layer 150 includes the reverse-taper portion (152A) that becomes thinner toward the flexible substrate 10 side. The thickness (tB) of the second conductor layer 150 on the flexible substrate 10 side is smaller than the thickness on the upper surface (the upper surface 145 of the electrolytic plating layer 140) side of the first conductor layer 110.

Therefore, the overall width (W) of the conductor layer 100 can be prevented from becoming excessively large.

In the embodiment, the motor 600 is formed by bonding the motor coil substrate 550 to the inner circumferential surface (560a) of the yoke 560 provided around the magnet 570. In the motor coil substrate 550 of the embodiment, the cylindricity of the outer circumferential surface (OC) is greater than 0.0 mm and equal to or less than 0.3 mm. Therefore, compared to a case where the cylindricity is 0.0 mm, the outer circumferential surface (OC) of the motor coil substrate 550 and the inner circumferential surface (560a) of the yoke 560 in a bonded state are less likely to slip, and the bonding strength is higher.

In the embodiment, by forming a compact motor 600 using a motor coil substrate 550 with a diameter of 50 mm or less, degradation in motor performance can be effectively suppressed. The diameter of the outer circumferential surface of the motor coil substrate 550 is measured using a caliper.

In the above, an example was described in which the coil substrate 2 is wound into a cylindrical shape to form the motor coil substrate 550. However, the present invention is not limited to this. The structure having the conductor layer 100 illustrated in FIG. 6 and the like can also be applied to a coil substrate that is used in a substantially flat plate shape without being wound into a cylindrical shape.

Japanese Patent Application Laid-Open Publication No. 2020-181853 describes a method for manufacturing a coil substrate. In Japanese Patent Application Laid-Open Publication No. 2020-181853, a copper foil is provided on a flexible substrate, an electrolytic plating film is formed on a seed layer exposed from a plating resist pattern provided on a surface of the copper foil, the plating resist pattern is peeled off, and the seed layer and the copper foil exposed from the electrolytic plating film are removed to form a wiring.

In Japanese Patent Application Laid-Open Publication No. 2020-181853, after peeling off the plating resist pattern, the seed layer and the copper foil exposed from the electrolytic plating film are removed by etching. Therefore, it is difficult to control wiring width or thickness within a predetermined range during pattern formation; when the wiring width or thickness becomes smaller than a predetermined value, wiring resistance may increase; and, conversely, when the wiring width or thickness becomes larger than a predetermined value, influence of eddy currents increases. In the coil substrate formed by the technology of Japanese Patent Application Laid-Open Publication No. 2020-181853, it is difficult to stably reduce the influence of wiring resistance or eddy currents.

A coil substrate according to an embodiment of the present invention includes: a resin substrate having a first surface and a second surface; and coil wirings formed on the first surface and the second surface of the resin substrate. The coil wirings are formed of a first conductor layer and an additional plating layer. The first conductor layer has a substantially trapezoidal cross-sectional shape with a lower base facing the resin substrate and an upper base on an opposite side with respect to the lower base. The additional plating layer covers upper and side surfaces of the first conductor layer.

A coil substrate according to another embodiment of the present invention includes: a resin substrate having a first surface and a second surface; and coil wirings formed on the first surface and the second surface of the resin substrate. The coil wirings are formed of a first conductor layer and an additional plating layer. The first conductor layer includes a metal foil layer, a chemical plating layer formed on the metal foil layer, and an electrolytic plating layer formed on the chemical plating layer. The first conductor layer has a substantially trapezoidal cross-sectional shape with a lower base facing the resin substrate and an upper base on an opposite side with respect to the lower base. The additional plating layer covers upper and side surfaces of the first conductor layer.

In the coil substrate, the coil wirings may have a width of 60 μm or more and 600 μm or less, and a thickness of 20 μm or more and 200 μm or less.

In the coil substrate, the coil wirings may have a width of 100 μm or more and 300 μm or less, and a thickness of 20 μm or more and 200 μm or less.

In the coil substrate, the coil wirings may have a width of 60 μm or more and 600 μm or less, and a thickness of 40 μm or more and 100 μm or less.

In the coil substrate, the coil wirings may have a width of 100 μm or more and 300 μm or less, and a thickness of 40 μm or more and 100 μm or less.

In the coil substrate, the side surface of the first conductor layer may have different inclination angles.

In the coil substrate, in a cross-sectional shape of the first conductor layer, an inclination of a side surface of the metal foil layer may be gentler than an inclination of a side surface of the electrolytic plating layer.

In the coil substrate, a thickness of a portion of the additional plating layer that covers the upper surface of the first conductor layer may be greater than a thickness of the first conductor layer.

In the coil substrate, a sidewall of the additional plating layer may include a reverse-taper portion that becomes thinner toward the resin substrate side.

A motor coil substrate according to another embodiment of the present invention is formed by winding the above coil substrate into a substantially cylindrical shape.

In the motor coil substrate, a space factor of the coil wirings may be 50% or more and 99% or less.

In the motor coil substrate, a space factor of the coil wirings may be 55% or more and 90% or less.

In the motor coil substrate, a space factor of the coil wirings may be 60% or more and 80% or less.

In the motor coil substrate, cylindricity of an outer circumferential surface of the motor coil substrate may be greater than 0.0 mm and equal to or less than 0.3 mm.

In the motor coil substrate, cylindricity of an outer circumferential surface of the motor coil substrate may be greater than 0.0 mm and equal to or less than 0.2 mm.

In the motor coil substrate, a space factor of the coil wirings may be 50% or more and 99% or less, and cylindricity of an outer circumferential surface of the motor coil substrate may be greater than 0.0 mm and equal to or less than 0.3 mm.

In the motor coil substrate, a space factor of the coil wirings may be 55% or more and 90% or less, and cylindricity of an outer circumferential surface of the motor coil substrate may be greater than 0.0 mm and equal to or less than 0.3 mm.

In the motor coil substrate, a space factor of the coil wirings may be 60% or more and 80% or less, and cylindricity of an outer circumferential surface of the motor coil substrate may be greater than 0.0 mm and equal to or less than 0.3 mm.

In the motor coil substrate, a space factor of the coil wirings may be 50% or more and 99% or less, and cylindricity of an outer circumferential surface of the motor coil substrate may be greater than 0.0 mm and equal to or less than 0.2 mm.

In the motor coil substrate, a space factor of the coil wirings may be 55% or more and 90% or less, and cylindricity of an outer circumferential surface of the motor coil substrate may be greater than 0.0 mm and equal to or less than 0.2 mm.

In the motor coil substrate, a space factor of the coil wirings may be 60% or more and 80% or less, and cylindricity of an outer circumferential surface of the motor coil substrate may be greater than 0.0 mm and equal to or less than 0.2 mm.

In the motor coil substrate, an outer diameter of the motor coil substrate may be 50 mm or less.

A motor according to another embodiment of the present invention is formed by providing one of a motor coil substrate and a magnet on a rotor and providing the other on a stator.

A method for manufacturing a coil substrate according to another embodiment of the present invention includes preparing a resin substrate having a metal foil layer formed on a first surface and a second surface; forming a through hole in the resin substrate, forming a chemical plating layer on a surface of the metal foil layer of the resin substrate in which the through hole is formed and in the through hole of the resin substrate; forming an electrolytic plating layer on a surface of the chemical plating layer using the chemical plating layer as a seed layer; forming a plating resist pattern on the electrolytic plating layer; forming a wiring pattern by removing the electrolytic plating layer, the chemical plating layer, and the metal foil layer exposed from the plating resist pattern by etching and then peeling off the plating resist pattern; and forming a conductor layer by forming a second conductor layer by electrolytic plating on an entire exposed surface of the wiring pattern. The coil substrate includes coil wirings formed on the first surface and the second surface of the resin substrate.

In an embodiment of the present invention, the additional plating layer is further formed to cover the upper and side surfaces of the first conductor layer, which is composed of the metal foil layer, the chemical plating layer, and the electrolytic plating layer. Therefore, the width and thickness of the coil wirings primarily formed by the first conductor layer can be supplemented and adjusted within predetermined ranges by the subsequent additional plating layer. In the coil substrate of the embodiment, the influence of wiring resistance or eddy currents can be stably reduced. Further, an effect of increasing the space factor of the coils is also achieved.

Obviously, numerous modifications and variations of the present invention are possible in light of the above teachings. It is therefore to be understood that within the scope of the appended claims, the invention may be practiced otherwise than as specifically described herein.

1. A coil substrate, comprising:
a resin substrate having a first surface and a second surface on an opposite side with respect to the first surface; and
a plurality of coil wirings formed on the first surface and the second surface of the resin substrate and comprising a first conductor layer and an additional plating layer,
wherein the plurality of coil wirings is formed such that the first conductor layer has a trapezoidal cross-sectional shape with a lower base facing the resin substrate and an upper base on an opposite side with respect to the lower base and that the additional plating layer is covering upper and side surfaces of the first conductor layer.

2. The coil substrate according to claim 1, wherein the plurality of coil wirings is formed such that the first conductor layer includes a metal foil layer, a chemical plating layer formed on the metal foil layer, and an electrolytic plating layer formed on the chemical plating layer.

3. The coil substrate according to claim 1, wherein the plurality of coil wirings is formed such that each of the coil wirings has a width in a range of 60 μm to 600 μm and a thickness in a range of 20 μm to 200 μm.

4. The coil substrate according to claim 1, wherein the plurality of coil wirings is formed such that each of the coil wirings has a width in a range of 100 μm to 300 μm and a thickness in a range of 20 μm to 200 μm.

5. The coil substrate according to claim 1, wherein the plurality of coil wirings is formed such that each of the coil wirings has a width in a range of 60 μm to 600 μm and a thickness in a range of 40 μm to 100 μm.

6. The coil substrate according to claim 1, wherein the plurality of coil wirings is formed such that each of the coil wirings has a width in a range of 100 μm to 300 μm and a thickness in a range of 40 μm to 100 μm.

7. The coil substrate according to claim 1, wherein the plurality of coil wirings is formed such that the side surface of the first conductor layer has different inclination angles.

8. The coil substrate according to claim 2, wherein the plurality of coil wirings is formed such that an inclination of a side surface of the metal foil layer is gentler than an inclination of a side surface of the electrolytic plating layer in a cross-sectional shape of the first conductor layer.

9. The coil substrate according to claim 1, wherein the plurality of coil wirings is formed such that the additional plating layer has a portion covering the upper surface of the first conductor layer and having a thickness that is greater than a thickness of the first conductor layer.

10. The coil substrate according to claim 1, wherein the additional plating layer has a sidewall including a reverse-taper portion that becomes thinner toward the resin substrate side.

11. A motor coil substrate, comprising:
the coil substrate of claim 1 wound into a cylindrical shape.

12. The motor coil substrate according to claim 11, wherein the coil substrate wound into the cylindrical shape has the coil wirings having a space factor in a range of 50% to 99%.

13. The motor coil substrate according to claim 11, wherein the coil substrate wound into the cylindrical shape has the coil wirings having a space factor in a range of 55% to 90%.

14. The motor coil substrate according to claim 11, wherein the coil substrate wound into the cylindrical shape has the coil wirings having a space factor in a range of 60% to 80%.

15. The motor coil substrate according to claim 11, wherein the coil substrate is wound into the cylindrical shape such that cylindricity of an outer circumferential surface of the motor coil substrate is in a range of greater than 0.0 mm to 0.3 mm.

16. The motor coil substrate according to claim 11, wherein the coil substrate is wound into the cylindrical shape such that cylindricity of an outer circumferential surface of the motor coil substrate is in a range of greater than 0.0 mm to 0.2 mm.

17. The motor coil substrate according to claim 11, wherein the coil substrate is wound into the cylindrical shape such that a space factor of the coil wirings is in a range of 50% to 99% and that cylindricity of an outer circumferential surface of the motor coil substrate is in a range of greater than 0.0 mm to 0.3 mm.

18. The motor coil substrate according to claim 11, wherein the coil substrate is wound into the cylindrical shape such that a space factor of the coil wirings is in a range of 55% to 90% and that cylindricity of an outer circumferential surface of the motor coil substrate is in a range of greater than 0.0 mm to less than 0.3 mm.

19. The motor coil substrate according to claim 11, wherein the coil substrate is wound into the cylindrical shape such that a space factor of the coil wirings is in a range of 60% to 80% and that cylindricity of an outer circumferential surface of the motor coil substrate is in a range of greater than 0.0 mm to 0.3 mm.

20. The motor coil substrate according to claim 11, wherein the coil substrate is wound into the cylindrical shape such that a space factor of the coil wirings is in a range of 50% to 99% and that cylindricity of an outer circumferential surface of the motor coil substrate is in a range of greater than 0.0 mm to 0.2 mm.

21. The motor coil substrate according to claim 11, wherein the coil substrate is wound into the cylindrical shape such that a space factor of the coil wirings is in a range of 55% to 90% and that cylindricity of an outer circumferential surface of the motor coil substrate is in a range of greater than 0.0 mm to 0.2 mm.

22. The motor coil substrate according to claim 11, wherein the coil substrate is wound into the cylindrical shape such that a space factor of the coil wirings is in a range of 60% to 80% and that cylindricity of an outer circumferential surface of the motor coil substrate is in a range of greater than 0.0 mm to 0.2 mm.

23. The motor coil substrate according to claim 11, wherein the coil substrate is wound into the cylindrical shape such that an outer diameter of the motor coil substrate is 50 mm or less.

24. A motor, comprising:
a rotor;
a stator;
a magnet positioned on one of the rotor and the stator; and
the motor coil substrate of claim 11 positioned on the other one of the rotor and the stator.

25. A method for manufacturing a coil substrate, comprising:
preparing a resin substrate having a first metal foil layer formed on a first surface and a second metal layer formed on a second surface of the resin substrate;
forming a through hole in the resin substrate such that the through hole penetrates through the resin substrate and the first and second metal foil layers;
forming a chemical plating layer on surfaces of the first and second metal foil layers on the resin substrate and in the through hole formed through the resin substrate;
forming an electrolytic plating layer on a surface of the chemical plating layer formed on the surfaces of the first and second metal foil layers on the resin substrate and in the through hole formed through the resin substrate;
forming a plating resist pattern on the electrolytic plating layer formed on the surface of the chemical plating layer on the surfaces of the first and second metal foil layers on the resin substrate;
etching exposed portions of the electrolytic plating layer, chemical plating layer, and first and second metal foil layers exposed from the plating resist pattern such that the exposed portions of the electrolytic plating layer, chemical plating layer, and first and second metal foil layers are removed;
peeling off the plating resist pattern from the electrolytic plating layer formed on the surface of the chemical plating layer such that wiring patterns forming a first conductor layer are formed on the first and second surfaces of the resin substrate; and
electrolytic plating on entire exposed surfaces of the wiring patterns such that a second conductor layer is formed on the entire exposed surfaces of the wiring patterns and that a plurality of coil wirings comprising the first conductor layer and the second conductor layer is formed on the first surface and the second surface of the resin substrate.
